(19) United States
(12) Patent Application Publication
(10) Pub. No.: US 2026/0223694 A1
(43) Pub. Date: Jul. 30, 2026

(54) SEMICONDUCTOR DEVICE AND METHOD OF MANUFACTURING SEMICONDUCTOR DEVICE

(71) Applicant: ROHM CO., LTD., Kyoto (JP)

(72) Inventor: Hiroaki MATSUBARA, Kyoto (JP)

(21) Appl. No.: 19/451,077

(22) Filed: Jan. 16, 2026

(30) Foreign Application Priority Data
Jan. 24, 2025 (JP) 2025-010508

(51) Int. Cl. H10W 70/40; H10W 70/04

(52) U.S. Cl. CPC H10W 70/424; H10W 70/048; H10W 70/457

(57) ABSTRACT

A semiconductor device includes: a semiconductor element; a plurality of leads; and a sealing resin, wherein the leads each include a body and a metal layer covering at least a portion of the body, wherein at least one of the leads includes a covered portion and an exposed portion, respectively covered with and exposed from the sealing resin, wherein the body in the exposed portion includes a bottom surface facing a first side in a thickness direction of the semiconductor element, an end surface with a tip facing a first direction intersecting the thickness direction, and a concave surface between the bottom and end surfaces, wherein the concave surface occupies only a portion of the body in a second direction intersecting the thickness direction and the first direction, and wherein the metal layer includes a bottom surface portion and a concave surface portion covering the bottom and concave surfaces respectively.

### CROSS-REFERENCE TO RELATED APPLICATION

This application is based upon and claims the benefit of priority from Japanese Patent Application No. 2025-010508, filed on January 24, 2025, the entire contents of which are incorporated herein by reference.

### TECHNICAL FIELD

The present disclosure relates to a semiconductor device and a method of manufacturing a semiconductor device.

### BACKGROUND

In the related art, there is known an example of a conventional semiconductor device. The semiconductor device in the related art includes a plurality of leads, which are used as portions to which solder is attached when the semiconductor device is mounted on a circuit board or the like.

### BRIEF DESCRIPTION OF DRAWINGS

The accompanying drawings, which are incorporated in and constitute a part of the specification, illustrate embodiments of the present disclosure.

FIG. 1 is a plan view showing a semiconductor device according to a first embodiment.

FIG. 2 is a view in which a sealing resin is indicated by an imaginary line in the plan view of FIG. 1.

FIG. 3 is a front view showing the semiconductor device according to the first embodiment.

FIG. 4 is a left side view showing the semiconductor device according to the first embodiment.

FIG. 5 is a right side view showing the semiconductor device according to the first embodiment.

FIG. 6 is a cross-sectional view taken along line VI-VI in FIG. 2.

FIG. 7 is a partially enlarged cross-sectional view for a portion of FIG. 6.

FIG. 8 is a cross-sectional view taken along line VIII-VIII in FIG. 2.

FIG. 9 is a partial cross-sectional view showing an internal structure of a semiconductor element of the semiconductor device according to the first embodiment.

FIG. 10 is a partially enlarged plan view showing a rod-shaped portion of the semiconductor device according to the first embodiment.

FIG. 11 is a partially enlarged bottom view showing the rod-shaped portion of the semiconductor device according to the first embodiment.

FIG. 12 is a partially enlarged cross-sectional view taken along line XII-XII in FIG. 10.

FIG. 13 is a partially enlarged cross-sectional view taken along line XIII-XIII in FIG. 10.

FIG. 14 is a flowchart showing an example of a method of manufacturing the semiconductor device according to the first embodiment.

FIG. 15 is a plan view showing a step of the method shown in FIG. 14.

FIG. 16 is a partially enlarged plan view showing a step of the method shown in FIG. 14.

FIG. 17 is a partially enlarged cross-sectional view taken along line XVII-XVII in FIG. 16.

FIG. 18 is a partially enlarged cross-sectional view taken along line XVIII-XVIII in FIG. 16.

FIG. 19 is a plan view showing a step of the method shown in FIG. 14.

FIG. 20 is a partially enlarged plan view showing a step of the method shown in FIG. 14.

FIG. 21 is a partially enlarged cross-sectional view taken along line XXI-XXI in FIG. 20.

FIG. 22 is a partially enlarged cross-sectional view taken along line XXII-XXII in FIG. 20.

FIG. 23 is a plan view showing a step of the method shown in FIG. 14.

FIG. 24 is a partially enlarged cross-sectional view showing a step of the method shown in FIG. 14.

FIG. 25 is a partially enlarged bottom view showing a rod-shaped portion of a first modification of the semiconductor device according to the first embodiment.

FIG. 26 is a partially enlarged bottom view showing a rod-shaped portion of a second modification of the semiconductor device according to the first embodiment.

FIG. 27 is a partially enlarged cross-sectional view showing a rod-shaped portion of a third modification of the semiconductor device according to the first embodiment.

FIG. 28 is a partially enlarged bottom view showing a rod-shaped portion of a semiconductor device according to a second embodiment.

FIG. 29 is a partially enlarged bottom view showing a rod-shaped portion of a semiconductor device according to a third embodiment.

FIG. 30 is a partially enlarged left side view showing a rod-shaped portion of a semiconductor device according to a fourth embodiment.

FIG. 31 is a partially enlarged cross-sectional view taken along line XXXI-XXXI in FIG. 30.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Preferred embodiments of the present disclosure are described in detail with reference to the drawings.

The terms "first," "second," "third," etc. in this disclosure are used merely for distinction purposes and are not intended to impose any ranking on their objects.

In the present disclosure, unless otherwise specified, "a certain object A is formed in a certain object B" and "a certain object A is formed on a certain object B" include "a certain object A is formed directly in a certain object B" and "a certain object A is formed in a certain object B with another object interposed between the certain object A and the certain object B." Similarly, unless otherwise specified, "a certain object A is disposed in a certain object B" and "a certain object A is disposed on a certain object B" include "a certain object A is disposed directly in a certain object B" and "a certain object A is disposed in a certain object B with another object interposed between the certain object A and the certain object B." Similarly, unless otherwise specified, "a certain object A is located on a certain object B" includes "a certain object A is located on a certain object B with the certain object A in contact with the certain object B" and "a certain object A is located on a certain object B with another object interposed between the certain object A and the certain object B." Further, unless otherwise specified, "a certain object A overlaps with a certain object B when viewed in a certain direction" includes "a certain object A overlaps with the entirety of a certain object B" and "a certain object A overlaps with a portion of a certain object B." In addition, in the present disclosure, "a surface A faces a direction B (one side or the other side of the direction B)" is not limited to a case where an angle of a surface A with respect to a direction B is 90 degrees, but also includes a case where a surface A is inclined with respect to a direction B.

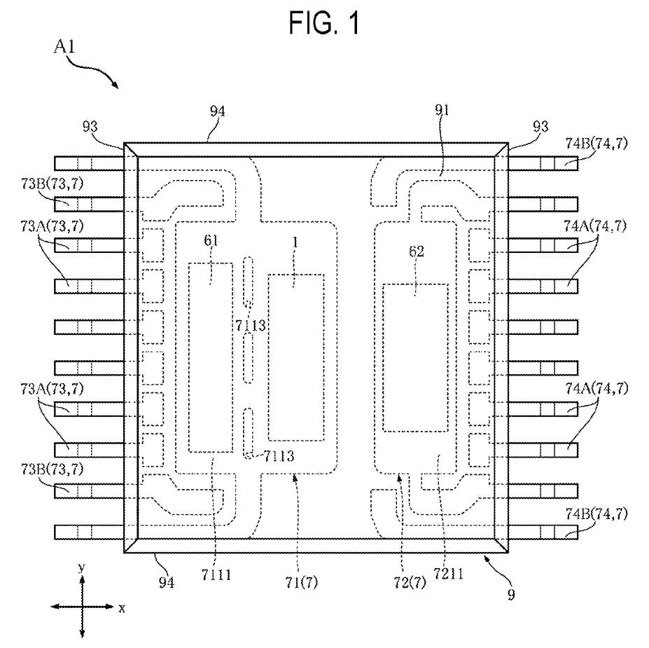

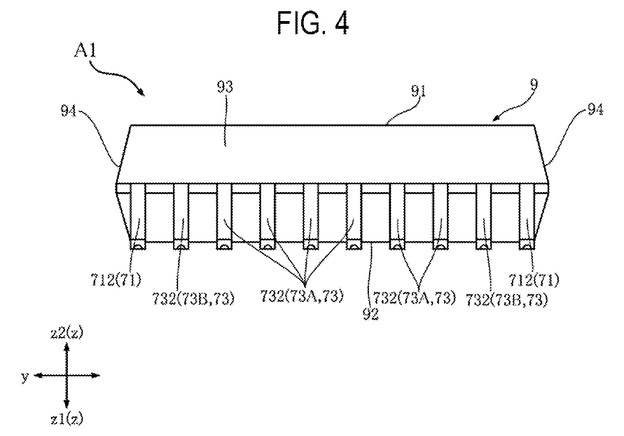

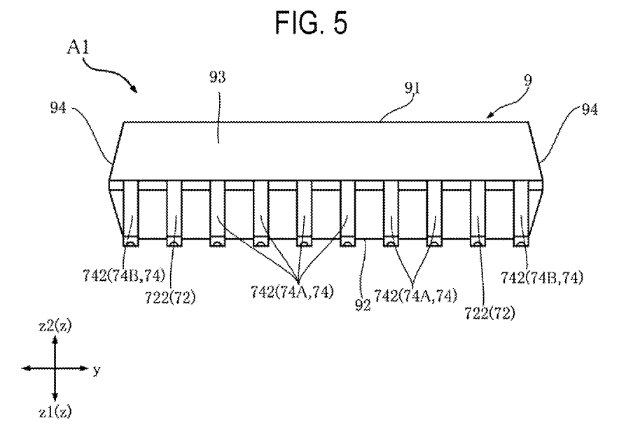

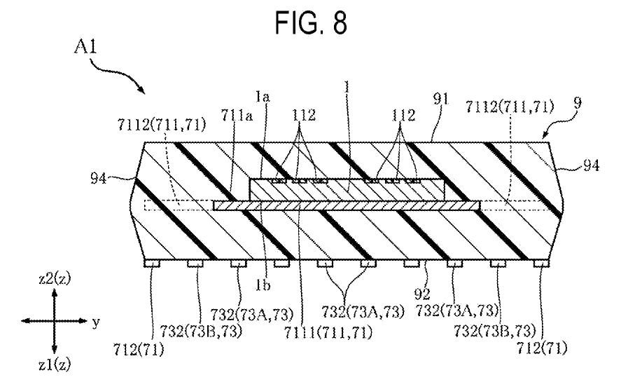

FIGS. 1 to 13 show a semiconductor device A1 according to a first embodiment. As shown in these figures, the semiconductor device A1 includes a semiconductor element 1, a first semiconductor element 61, a second semiconductor element 62, leads 7, a plurality of connecting members 8, and a sealing resin 9. The leads 7 include a plurality of leads 71 to 74, and the plurality of connecting members 8 include a plurality of wires 81, 82, and 84 to 87.

In these figures, a thickness direction in the present disclosure is defined as a thickness direction z. A first side in the thickness direction z is referred to as a z1 side, and a second side opposite the first side in the z direction is referred to as a z2 side. A direction perpendicular to the thickness direction z is defined as a first direction x. A direction perpendicular to the thickness direction z and the first direction x is defined as a second direction y.

The semiconductor device A1 is used in, for example, electric vehicles or hybrid vehicles. The semiconductor device A1 controls a switching operation of a switching element such as an IGBT or a MOSFET. As can be seen from FIG. 1 and FIGS. 3 to 5, a package format of the semiconductor device A1 is a small outline package (SOP). However, the package format of the semiconductor device A1 is not limited to the SOP.

The first semiconductor element 61 is a controller (control element) of a gate driver that drives a switching element such as an IGBT, a MOSFET, etc. The first semiconductor element 61 includes a circuit that converts a control signal input from an ECU or the like into a PWM control signal, a transmission circuit that transmits the PWM control signal to the semiconductor element 1, and a reception circuit that receives an electrical signal from the semiconductor element 1.

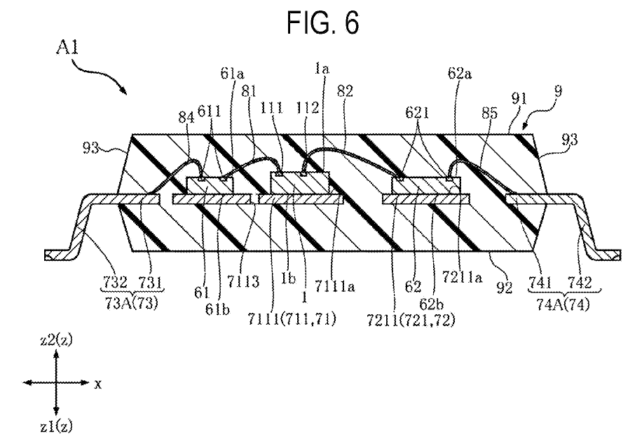

As shown in FIG. 6, the first semiconductor element 61 includes a main surface 61a and a back surface 61b. The main surface 61a and the back surface 61b are spaced apart in the thickness direction z. The main surface 61a is an upper surface of the first semiconductor element 61, and the back surface 61b is a lower surface of the first semiconductor element 61. The back surface 61b faces the leads 71.

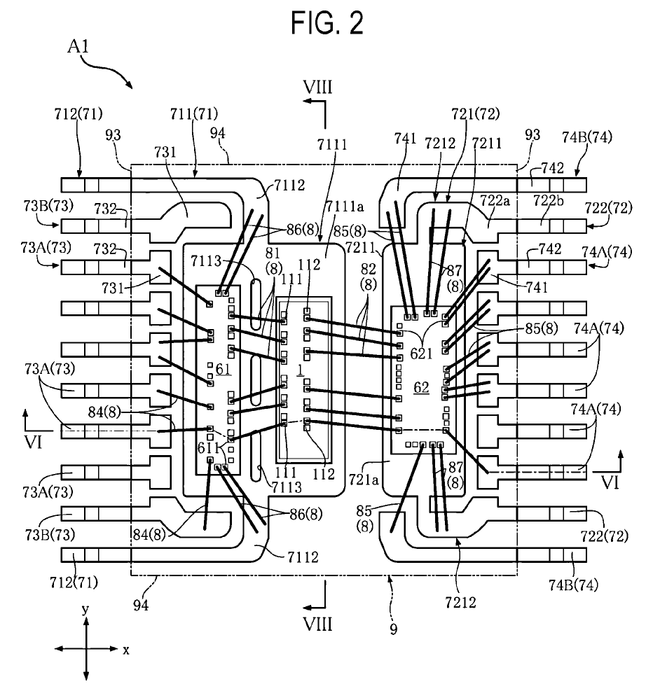

As shown in FIGS. 2 and 6, the first semiconductor element 61 includes a plurality of pads 611. The plurality of pads 611 are provided on the main surface 61a (a surface facing in the same direction as a mounting surface 7111a of an island portion 7111 of the lead 71, which is described later). Each of the plurality of pads 611 contains, for example, Cu (copper).

The second semiconductor element 62 is a gate driver (drive element) for driving a switching element. The second semiconductor element 62 includes a reception circuit for receiving a PWM control signal, a circuit for driving the switching element based on the PWM control signal, and a transmission circuit for transmitting an electrical signal to the first semiconductor element 61. An example of the electrical signal is an output signal from a temperature sensor disposed near a motor.

As shown in FIG. 6, the second semiconductor element 62 includes a main surface 62a and a back surface 62b. The main surface 62a and the back surface 62b are spaced apart in the thickness direction z. The main surface 62a is an upper surface of the second semiconductor element 62, and the back surface 62b is a lower surface of the second semiconductor element 62. The back surface 62b faces the leads 72.

As shown in FIGS. 2 and 6, the second semiconductor element 62 includes a plurality of pads 621. The plurality of pads 621 are provided on the main surface 62a (a surface facing in the same direction as a mounting surface 7211a of an island portion 7211 of the lead 72, which is described later). Each of the plurality of pads 621 contains, for example, Cu (copper).

The semiconductor element 1 is an element (insulating element) for transmitting a PWM control signal and other electrical signals in an insulated state. The semiconductor element 1 is an inductive type. An example of the inductive type semiconductor element 1 is an insulating transformer. The semiconductor element 1 may also be a capacitive type. An example of the capacitive type semiconductor element 1 is a capacitor. Alternatively, the semiconductor element 1 may be a photocoupler.

As shown in FIGS. 6 to 9, the semiconductor element 1 includes a main surface 1a and a back surface 1b. The main surface 1a and the back surface 1b are spaced apart in the thickness direction z. The main surface 1a is an upper surface of the semiconductor element 1, and the back surface 1b is a lower surface of the semiconductor element 1. The back surface 1b faces the leads 71.

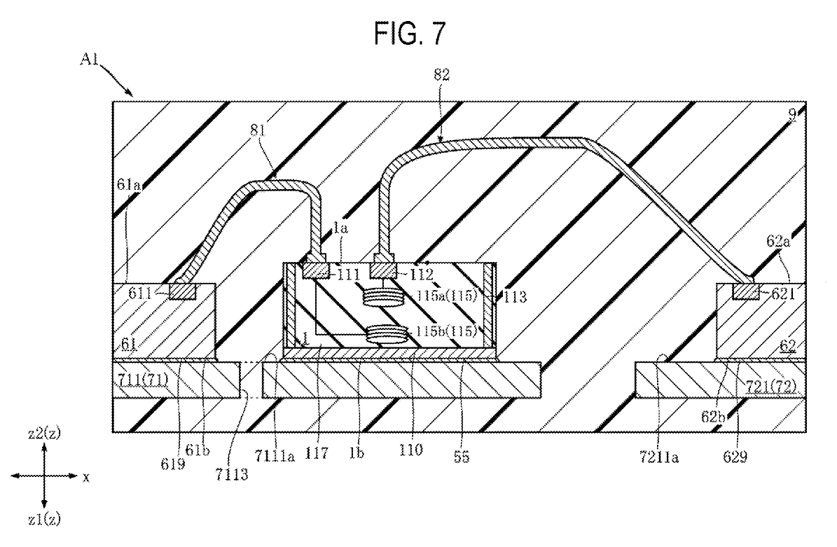

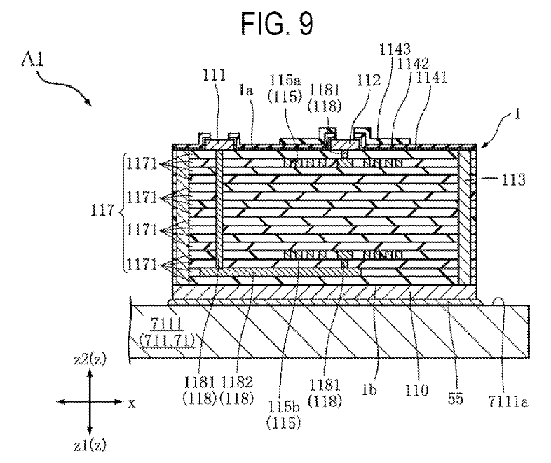

The semiconductor element 1 includes a functional part 115. The functional part 115 includes a plurality of sets of upper windings 115a and lower windings 115b, each set consisting of an upper winding 115a and a lower winding 115b. That is, the semiconductor element 1 includes a plurality of upper windings 115a and a plurality of lower windings 115b. FIGS. 7 and 9 illustrate one of the plurality of sets of upper windings 115a and lower windings 115b. For example, the plurality of sets of upper windings 115a and lower windings 115b are arranged along a longitudinal direction (second direction y) of the semiconductor element 1. The upper winding 115a and the lower winding 115b in one set are spaced apart in the thickness direction z and face each other in the thickness direction z. In this embodiment, each of the upper winding 115a and the lower winding 115b in a set is planarly wound in a spiral shape. The upper winding 115a and the lower winding 115b in a set are magnetically coupled to each other. The first semiconductor element 61 inductively couples the upper winding 115a and the lower winding 115b in each set, thereby transmitting electrical signals in an insulated state.

As shown in FIGS. 2, 6 and 7, the semiconductor element 1 includes a plurality of pads 111 and 112. The plurality of pads 111 and 112 are each provided on the main surface 1a. As shown in FIG. 7, each pad 111 is electrically connected to one of the plurality of lower windings 115b, and each pad 112 is electrically connected to one of the plurality of upper windings 115a. A composition of each of the plurality of pads 111 and 112 includes, for example, aluminum. As shown in FIGS. 2, 6 and 7, each of the plurality of pads 111 is bonded to one of the plurality of wires 81, and each of the plurality of pads 112 is bonded to one of the plurality of wires 82.

As shown in FIGS. 2 and 7, the semiconductor element 1 includes a seal ring portion 113. In a plan view, the seal ring portion 113 is formed along each of four outer peripheral sides of the semiconductor element 1 to surround an outer periphery of a circuit formation region. The seal ring portion 113 is made of, for example, copper (Cu), aluminum (Al), and the like.

As shown in FIGS. 7 and 9, the semiconductor element 1 includes a semiconductor substrate 110, a protective film 1141, a passivation film 1142, a coil protection film 1143, a laminated structure 117, and a wiring portion 118.

The semiconductor substrate 110 may be a Si (silicon) substrate, a SiC (silicon carbide) substrate, or the like. The semiconductor element 1 may use an insulating substrate such as a ceramic substrate or a resin substrate instead of the semiconductor substrate 110. The seal ring portion 113 is provided upright on the semiconductor substrate 110 and penetrates the laminated structure 117 in the thickness direction z. In this embodiment, a potential of the seal ring portion 113 is substantially the same as a potential of the semiconductor substrate 110.

The laminated structure 117 is formed on the semiconductor substrate 110. As shown in FIG. 9, the laminated structure 117 includes a plurality of insulating layers 1171. The plurality of insulating layers 1171 are stacked on an upper surface of the semiconductor substrate 110. Except for the lowermost insulating layer 1171 in contact with the upper surface of the semiconductor substrate 110, each of the plurality of insulating layers 1171 is formed of a laminated structure including a lower etching stopper film and an upper interlayer insulating film. The lowermost insulating layer 1171 is formed solely of an interlayer insulating layer. Examples of the etching stopper film include a SiN film (silicon nitride film), a SiC film (silicon carbide film), a SiCN film (silicon carbonitride film), and the like. An example of the interlayer insulating film includes a SiO₂ film (silicon oxide film). A dimension of the plurality of insulating layers 1171 in the thickness direction z is not particularly limited, and may be, for example, 2.4 μm. Thicknesses of the plurality of insulating layers 1171 may be the same or different.

The upper winding 115a and the lower winding 115b are formed in different insulating layers 1171 in the laminated structure 117 and face each other with at least one insulating layer 1171 interposed therebetween. In the illustrated example, the lower winding 115b is formed in the fourth insulating layer 1171 counted from the semiconductor substrate 110, and the upper winding 115a is formed on the fifteenth insulating layer 1171 with ten insulating layers 1171 sandwiched between the upper winding 115a and the lower winding 115b. The number of insulating layers 1171 is not limited to the illustrated example and may be changed appropriately depending on, for example, a magnitude of a voltage applied to each pad 111 and each pad 112. The greater the number of insulating layers 1171 between the upper winding 115a and the lower winding 115b, the higher the dielectric withstand voltage of the semiconductor element 1, but the greater the thickness (dimension in the thickness direction z) of the semiconductor element 1. On the other hand, the fewer the number of insulating layers 1171 between the upper winding 115a and the lower winding 115b, the lower the dielectric withstand voltage of the semiconductor element 1, but the smaller the thickness of the semiconductor element 1 (the dimension in the thickness direction z).

The wiring portion 118 electrically connects the pads 111 and 112 to the upper winding 115a and the lower winding 115b. The wiring portion 118 includes a plurality of through-wires 1181 and lead-out wires 1182. As shown in FIG. 9, each of the plurality of through-wires 1181 penetrates one or more insulating layers 1171 in the thickness direction z. In the example shown in FIG. 9, the plurality of through-wires 1181 includes a through-wire that connects the pad 111 to the lead-out wire 1182, a through-wire that connects the lead-out wire 1182 to the lower winding 115b, and a through-wire that connects the pad 112 to the upper winding 115a. The lead-out wires 1182 are formed above the lowermost insulating layer 1171. The lead-out wires 1182 form a portion of a conductive path between the pad 111 and the lower winding 115b.

As shown in FIG. 9, the protective film 1141 is stacked on the laminated structure 117. As shown in FIG. 9, the passivation film 1142 is stacked on the protective film 1141. As shown in FIG. 9, the coil protection film 1143 is on the passivation film 1142 and selectively covers a region directly above the upper winding 115a. As can be seen from FIG. 9, pad openings are formed in the protective film 1141, the passivation film 1142, and the coil protection film 1143 to expose each pad 111 and each pad 112. The protective film 1141 contains, for example, SiO₂ and has a thickness of approximately 150 nm. The passivation film 1142 contains, for example, SiN and has a thickness of approximately 1,000 nm. The coil protection film 1143 contains, for example, polyimide and has a thickness of approximately 4,000 nm. The constituent materials and thicknesses of the protective film 1141, the passivation film 1142, and the coil protection film 1143 are not limited to the examples described above.

A structure of the semiconductor element 1 is not limited to the above example. For example, each of the upper winding 115a and the lower winding 115b is not limited to being planarly wound on a single insulating layer 1171, and may be wound three-dimensionally across a plurality of insulating layers 1171. However, in order to prevent the thickness of the semiconductor element 1 from increasing, it is desirable that each of the upper winding 115a and the lower winding 115b is planarly wound on a single insulating layer 1171.

In the semiconductor device A1, the second semiconductor element 62 requires a power supply voltage higher than that required for the first semiconductor element 61. This creates a potential difference between the first semiconductor element 61 and the second semiconductor element 62. Therefore, a first circuit including the first semiconductor element 61 as a component and a second circuit including the second semiconductor element 62 as a component are insulated from each other by the semiconductor element 1. Components of the first circuit include the lead 71, the plurality of leads 73, the plurality of wires 81, 84, and 86, and portions of the semiconductor element 1 (such as the pads 111 and the lower windings 115b), in addition to the first semiconductor element 61. Components of the second circuit include the lead 72, the plurality of leads 74, the plurality of wires 82, 85, and 87, and portions of the semiconductor element 1 (such as the pads 112 and the upper windings 115a), in addition to the second semiconductor element 62. The first circuit and the second circuit have relatively different potentials. In the semiconductor device A1, the potential of the second circuit is higher than the potential of the first circuit. Then, the semiconductor element 1 relays signals between the first circuit and the second circuit. For example, in an inverter device for an electric vehicle or hybrid vehicle, a voltage applied to the ground of the first semiconductor element 61 may be approximately 0 V, while a voltage applied to the ground of the second semiconductor element 62 may transiently reach 600 V or higher. Depending on specifications of the inverter device, the voltage applied to the ground of the second semiconductor element 62 may reach 3,750 V or higher.

The semiconductor device A1 may include the leads 7. The leads 7 form conductive paths between a wiring board on which the semiconductor device A1 is mounted and the plurality of semiconductor elements 1, the first semiconductor element 61, and the second semiconductor element 62. The leads 7 are obtained, for example, from the same lead frame. The leads 7 include the lead 71, the lead 72, the plurality of leads 73, and the plurality of leads 74.

As shown in FIGS. 1 and 2, the leads 71 and 72 are spaced apart from each other in the first direction x. In the semiconductor device A1, the semiconductor element 1 and the first semiconductor element 61 are mounted on the lead 71, and the second semiconductor element 62 is mounted on the lead 72.

As shown in FIG. 2, the lead 71 includes a covered portion 711 and an exposed portion 712. The covered portion 711 is covered with the sealing resin 9. The exposed portion 712 is exposed from the sealing resin 9.

The covered portion 711 includes an island portion 7111 and two extension portions 7112.

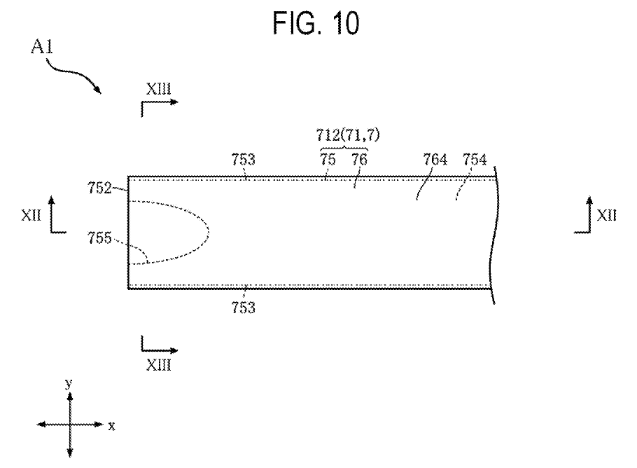

As shown in FIGS. 6 and 7, the island portion 7111 includes a mounting surface 7111a facing the second side z2 in the thickness direction z. As shown in FIGS. 7 and 10, the semiconductor element 1 is bonded to the mounting surface 7111a via a bonding material 55, and the first semiconductor element 61 is bonded to the mounting surface 7111a via a conductive bonding material 619. The conductive bonding material 619 is, for example, solder, metal paste, sintered metal, or the like. The bonding material 55 may be, for example, solder, metal paste, sintered metal, or insulating adhesive. The island portion 7111 is covered with the sealing resin 9. In the illustrated example, the island portion 7111 has a rectangular shape in a plan view. A thickness of the island portion 7111 is, for example, 100 μm or more and 300 μm or less.

As shown in FIGS. 2, 6 and 7, a plurality of through-holes 7113 are formed at the island portion 7111. Each of the plurality of through-holes 7113 penetrates the island portion 7111 in the thickness direction z and extends along the second direction y. In a plan view, at least one of the plurality of through-holes 7113 is located between the semiconductor element 1 and the first semiconductor element 61. The plurality of through-holes 7113 are arranged along the second direction y. Unlike the illustrated example, the island portion 7111 may not have the plurality of through-holes 7113 formed therein.

As shown in FIG. 2, the two extension portions 7112 extend from both sides of the island portion 7111 in the second direction y. The two extension portions 7112 are spaced apart from each other in the second direction y. At least one of the two extension portions 7112 is electrically connected to the ground of the first semiconductor element 61 via one of the plurality of wires 86.

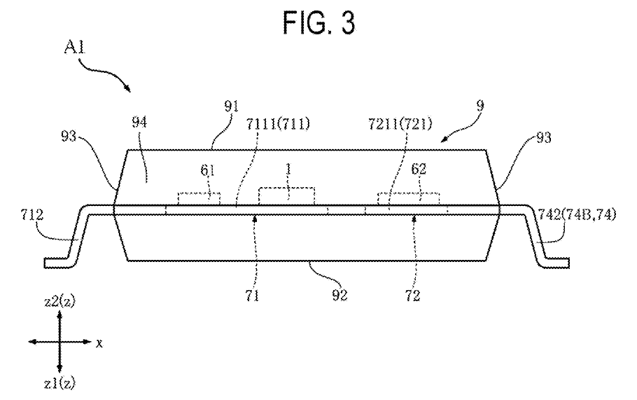

In a plan view, the exposed portion 712 extends along the first direction x. As shown in FIG. 3, the exposed portion 712 is bent in a gull-wing shape when viewed in the second direction y.

As shown in FIG. 2, the lead 72 includes a covered portion 721 and an exposed portion 722. The covered portion 721 is covered with the sealing resin 9. The exposed portion 722 is exposed from the sealing resin 9.

The covered portion 721 includes an island portion 7211 and two extension portions 7212.

As shown in FIGS. 6 and 7, the island portion 7211 includes a mounting surface 7211a facing the second side z2 in the thickness direction z. As shown in FIG. 7, the second semiconductor element 62 is bonded to the mounting surface 7211a via a conductive bonding material 629. Each of the conductive bonding materials 619 and 629 is, for example, solder, metal paste, sintered metal, or the like. The island portion 7211 is covered with the sealing resin 9. In the illustrated example, the island portion 7211 has a rectangular shape in a plan view. Just like the island portion 7111, a thickness of the island portion 7211 is, for example, 100 μm or more and 300 μm or less.

As shown in FIG. 2, the two extension portions 7212 extend from both sides of the island portion 7211 in the second direction y. The two extension portions 7212 are spaced apart from each other in the second direction y. At least one of the two extension portions 7212 is electrically connected to the ground of the second semiconductor element 62 via one of the plurality of wires 87.

In a plan view, the exposed portion 722 extends along the first direction x. As shown in FIG. 3, the exposed portion 722 is bent in a gull-wing shape when viewed in the second direction y.

As shown in FIGS. 1 and 2, the plurality of leads 73 are located on an opposite side of the island portion 7111 of the lead 71 from the island portion 7211 of the lead 72 in the first direction x. The plurality of leads 73 are arranged along the second direction y. At least one of the plurality of leads 73 is electrically connected to the first semiconductor element 61 via one of the plurality of wires 84. The plurality of leads 73 include a plurality of (six in the illustrated example) intermediate leads 73A and two side leads 73B. The two side leads 73B are located on either side of the plurality of intermediate leads 73A in the second direction y. Each of the two side leads 73B is located between one of the two extension portions 7112 of the lead 71 and the intermediate lead 73A located closest to the one extension portion 7112 in the second direction y.

As shown in FIGS. 2 and 6, each of the leads 73 (the intermediate leads 73A and the two side leads 73B) includes a covered portion 731 and an exposed portion 732. The covered portion 731 is covered with the sealing resin 9. In the illustrated example, a dimension of each of the covered portions 731 of the two side leads 73B in the first direction x is larger than a dimension of each of the covered portions 731 of the intermediate leads 73A in the first direction x. As shown in FIGS. 2 and 6, the exposed portion 732 is connected to the covered portion 731 and exposed from the sealing resin 9. In a plan view, the exposed portion 732 extends along the first direction x. As can be seen from FIGS. 2 to 4, the exposed portion 732 is bent in a gull-wing shape when viewed along the second direction y. The shape of the exposed portion 732 is the same as the shape of each exposed portion 712 of the leads 71.

The shape, arrangement, and number of the leads 73 are not limited to those shown in the illustrated example. For example, the number of leads 73 may be more or less than the eight shown in the illustrated example. In addition, for example, some of the leads 73 may be disposed more outward than either of the two extension portions 7112 of the leads 71.

As shown in FIGS. 1 and 2, the plurality of leads 74 are located on an opposite side of the island portions 7111 of the leads 71 from the plurality of leads 73 in the first direction x. The plurality of leads 74 are arranged along the second direction y. At least one of the plurality of leads 74 is electrically connected to the second semiconductor element 62 via one of the plurality of wires 85. The plurality of leads 74 include a plurality of (six in the illustrated example) intermediate leads 74A and two side leads 74B. The two side leads 74B are located on either side of the plurality of intermediate leads 74A in the second direction y. In the second direction y, one of the two extension portions 7212 of the leads 72 is located between one of the two side leads 74B and the intermediate lead 74A located closest to the one side lead 74B.

As shown in FIGS. 2 and 6, each of the leads 74 (the plurality of intermediate leads 74A and the two side leads 74B) includes a covered portion 741 and an exposed portion 742. The covered portion 741 is covered with the sealing resin 9. In the illustrated example, a dimension of each of the covered portions 741 of the two side leads 74B in the first direction x is larger than a dimension of each of the covered portions 741 of the intermediate leads 74A in the first direction x. As shown in FIGS. 2 and 6, the exposed portion 742 is connected to the covered portion 741 and exposed from the sealing resin 9. In a plan view, the exposed portion 742 extends along the first direction x. As can be seen from FIGS. 2, 3, and 5, the exposed portion 742 is bent in a gull-wing shape when viewed along the second direction y. The shape of the exposed portion 742 is the same as the shape of the two exposed portions 722 of the leads 72.

The shape, arrangement, and number of the leads 74 are not limited to the illustrated example. For example, the number of leads 74 may be more or less than those of the illustrated example (eight). In addition, for example, each of the two side leads 74B may be located between one of the two extension portions 7212 of the leads 72 and the intermediate lead 74A located closest to the one extension portion 7212 in the second direction y.

Each of the lead 71, the lead 72, the lead 73, and the lead 74 includes a body 75 and a metal layer 76. The body 75 may contain a metal such as Cu (copper), Ni (nickel), Fe (iron), or the like, or an alloy of the metal. The metal layer 76 covers at least a portion of the body 75 and may be composed of a single layer or a plurality of layers containing a metal such as Sn (tin), Ni (nickel), Pd (palladium), Au (gold), Ag (silver), or the like, or an alloy of the metal.

FIGS. 10 to 13 show the exposed portion 712 in more detail. A specific configuration described with reference to these figures may be similarly provided for the exposed portion 722, the exposed portion 732, and the exposed portion 742. In this embodiment, the exposed portion 712, the exposed portion 722, the exposed portion 732, and the exposed portion 742 include the same configuration.

The body 75 in the exposed portion 712 may include a bottom surface 751, an end surface 752, two side surfaces 753, a top surface 754, and a concave surface 755. The bottom surface 751 faces the z1 side in the thickness direction z. The top surface 754 faces the z2 side in the thickness direction z. The end surface 752 is located at a tip of the exposed portion 712 and is located between the top surface 754 and the concave surface 755 in the thickness direction z. In the illustrated example, the end surface 752 faces the first direction x. The two side surfaces 753 are located on both sides of the first direction x and are located between the bottom surface 751 and the top surface 754 in the thickness direction z.

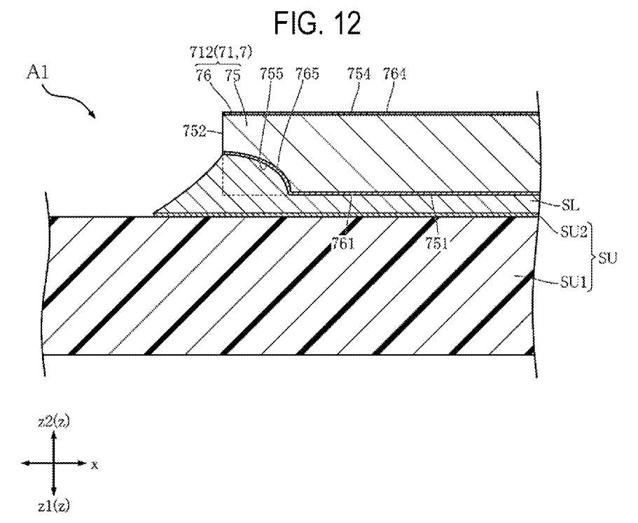

The concave surface 755 is located between the bottom surface 751 and the end surface 752. As shown in FIG. 12, the concave surface 755 is recessed toward the z2 side from the bottom surface 751 in the thickness direction z. The concave surface 755 is also recessed inward (to the right in the figure) from the end surface 752 in the first direction x. A depth of the concave surface 755 in the thickness direction z is not particularly limited, and may be, for example, ¼ times or more and ¾ times or less of a thickness of the exposed portion 712 of the body 75 in the thickness direction z.

The concave surface 755 occupies only a portion of the body 75 in the second direction y. In the illustrated example, the concave surface 755 is spaced apart from the two side surfaces 753 in the second direction y.

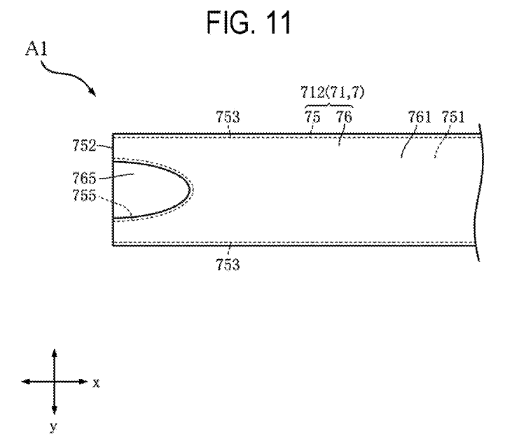

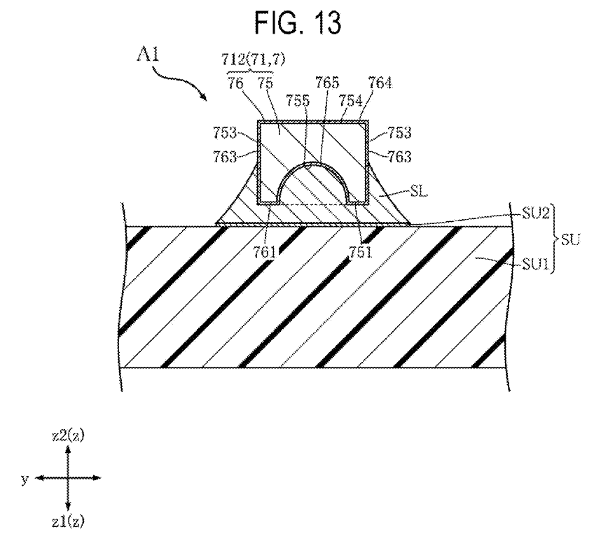

A specific shape of the concave surface 755 is not particularly limited. The concave surface 755 may be semicircular, semielliptical, polygonal, or the like when viewed in the thickness direction z. As shown in FIGS. 10 and 11, in the illustrated example, the concave surface 755 is semielliptical when viewed in the thickness direction z. A three-dimensional shape of the concave surface 755 may be, for example, a concavely curved surface, a bent surface, or the like. As shown in FIGS. 12 and 13, in the illustrated example, the concave surface 755 is configured as a concavely curved surface. A size of the concave surface 755 in the second direction y increases as the concave surface 755 approaches the first side z1 in the thickness direction z.

The metal layer 76 in the exposed portion 712 may include a bottom surface portion 761, two side surface portions 763, a top surface portion 764, and a concave surface portion 765. The bottom surface portion 761 covers the bottom surface 751. The two side surface portions 763 cover the two side surfaces 753. The top surface portion 764 covers the top surface 754. The concave surface portion 765 covers the concave surface 755. The concave surface portion 765 may cover at least a portion of the concave surface 755. In the illustrated example, the concave surface portion 765 is connected to the bottom surface 751. Further, the concave surface portion 765 covers the entire concave surface 755. The end surface 752 may be entirely exposed from the metal layer 76.

Each of the plurality of connecting members 8 provides electrical connection between two portions spaced apart from each other. As described above, the plurality of connecting members 8 include the plurality of wires 81, 82, and 84 to 87. The plurality of connecting members 8 may be bonding ribbons or plate-shaped metal members instead of the plurality of wires 81, 82, and 84 to 87 (bonding wires).

Each of the wires 81, 82, and 84 to 87 contains a metal material such as copper or a copper alloy (e.g., a palladium-copper alloy). That is, each of the wires 81, 82, and 84 to 87 is a copper wire. Each of the wires 81, 82, and 84 to 87 may include a core (containing, e.g., copper) and a surface layer (containing, e.g., palladium) covering the core. In this embodiment, the wires 82 and 84 to 87 may be configured to contain gold, aluminum, or silver as the metal material, rather than copper or a copper alloy.

As shown in FIGS. 2 and 7, each of the plurality of wires 81 is bonded to one of the plurality of pads 111 of the semiconductor element 1 and one of the plurality of pads 611 of the first semiconductor element 61. Each wire 81 electrically connects the semiconductor element 1 and the first semiconductor element 61. The plurality of wires 81 are arranged along the second direction y.

As shown in FIGS. 2 and 7, each of the plurality of wires 82 is bonded to one of the plurality of pads 112 of the semiconductor element 1 and one of the plurality of pads 621 of the second semiconductor element 62. Each of the wires 82 electrically connects the semiconductor element 1 and the second semiconductor element 62. The plurality of wires 82 are arranged along the second direction y. Each of the plurality of wires 82 straddles the island portion 7111 of the lead 71 and the island portion 7211 of the lead 72 in a plan view.

As shown in FIG. 2, each of the plurality of wires 84 is bonded to one of the plurality of pads 611 of the first semiconductor element 61 and to the covered portion 731 of one of the plurality of leads 73. Each of the wires 84 electrically connects the first semiconductor element 61 and one of the plurality of leads 73.

As shown in FIG. 2, each of the plurality of wires 85 is bonded to one of the plurality of pads 621 of the second semiconductor element 62 and to the covered portion 741 of one of the plurality of leads 74. Each of the wires 85 electrically connects the second semiconductor element 62 and one of the plurality of leads 74.

As shown in FIG. 2, each of the plurality of wires 86 is bonded to one of the plurality of pads 611 of the first semiconductor element 61 and to the two extension portions 7112. Each of the plurality of wires 86 electrically connects the first semiconductor element 61 and the lead 71. The number of wires 86 is not limited to two or more, and may be one.

As shown in FIG. 2, each of the plurality of wires 87 is bonded to one of the plurality of pads 621 of the second semiconductor element 62 and one of the two extension portions 7212. Each of the plurality of wires 87 electrically connects the second semiconductor element 62 and the lead 72. The number of the plurality of wires 87 is not limited to two or more, and may be one.

As shown in FIG. 1, the sealing resin 9 covers the semiconductor element 1, the first semiconductor element 61, the second semiconductor element 62, portions of the leads 7, and the plurality of connecting members 8. The sealing resin 9 has electrical insulating properties. The sealing resin 9 insulates components of the first circuit (e.g., the leads 71) and components of the second circuit (e.g., the leads 72) from each other. The sealing resin 9 is made of a material including, for example, a black epoxy resin. In the illustrated example, the sealing resin 9 has a rectangular shape in a plan view.

As shown in FIGS. 2 to 5, the sealing resin 9 includes a top surface 91, a bottom surface 92, a pair of side surfaces 93, and a pair of side surfaces 94.

As shown in FIGS. 3 to 5, the top surface 91 and the bottom surface 92 are spaced apart from each other in the thickness direction z. The top surface 91 and the bottom surface 92 face opposite sides in the thickness direction z. Each of the top surface 91 and the bottom surface 92 is substantially flat.

As shown in FIGS. 3 to 5, the pair of side surfaces 93 are connected to the top surface 91 and the bottom surface 92, and are spaced apart from each other in the first direction x. Two exposed portions 712 and each exposed portion 732 of the plurality of leads 73 are exposed from the side surface 93 located on one side in the first direction x. Two exposed portions 722 and each exposed portion 742 of the plurality of leads 74 are exposed from the side surface 93 located on the other side in the first direction x.

As shown in FIGS. 3 to 5, the pair of side surfaces 94 are connected to the top surface 91 and the bottom surface 92, and are spaced apart from each other in the second direction y. As shown in FIG. 1, the lead 71, the lead 72, the plurality of leads 73, and the plurality of leads 74 are spaced apart from the pair of side surfaces 94.

The semiconductor device A1 is not limited to certain applications, and may be used, for example, in an inverter device for an electric vehicle. A motor driver circuit for the inverter device is generally composed of a half-bridge circuit including a low-side (low potential side) switching element and a high-side (high potential side) switching element. The following description focuses on the case where these switching elements are MOSFETs.

In the low-side switching element, reference potentials of a source of the switching element and a gate driver that drives the switching element are both grounded, whereas in the high-side switching element, reference potentials of a source of the switching element and a gate driver that drives the switching element both correspond to a potential at an output node of the half-bridge circuit.

The potential at the output node is changed in response to driving of the high-side switching element and the low-side switching element, and therefore the reference potential of the gate driver that drives the high-side switching element is changed. When the high-side switching element is turned on, the reference potential becomes equivalent to a voltage applied to a drain of the high-side switching element (e.g., 600 V or higher). In the semiconductor device A1, the ground of the first semiconductor element 61 and the ground of the second semiconductor element 62 are separated. Therefore, when the semiconductor device A1 is used as the gate driver for driving the high-side switching element, a voltage equivalent to a voltage applied to the drain of the high-side switching element is transiently applied to the ground of the second semiconductor element 62.

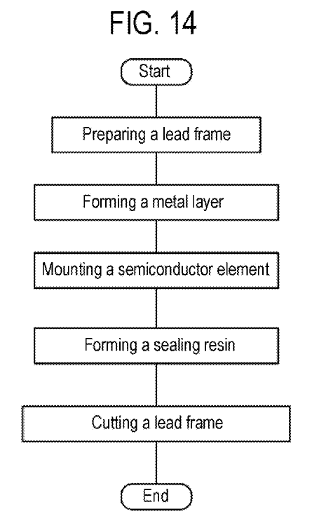

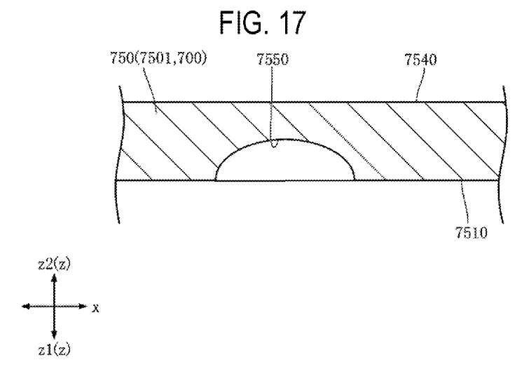

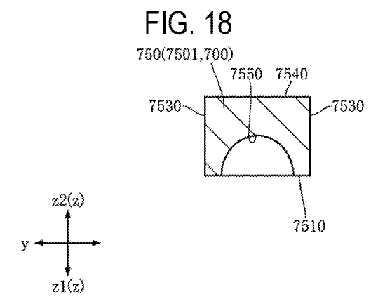

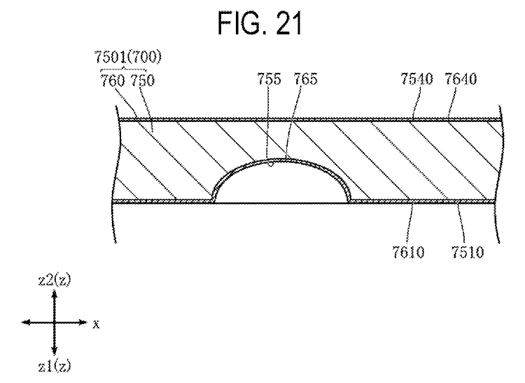

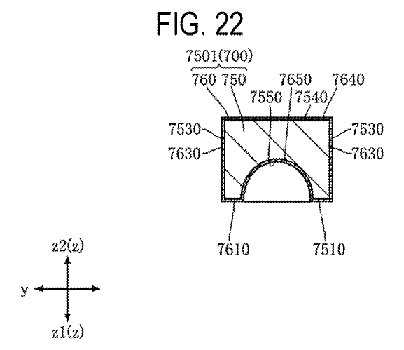

Next, an example of a method of manufacturing the semiconductor device A1 is described below with reference to FIGS. 14 to 24.

As shown in FIG. 14, the method of manufacturing the semiconductor device A1 according to this embodiment includes a step of preparing a lead frame 700, a step of forming a metal layer 760, a step of mounting a semiconductor element 1, a step of forming a sealing resin 9, and a step of cutting the lead frame 700.

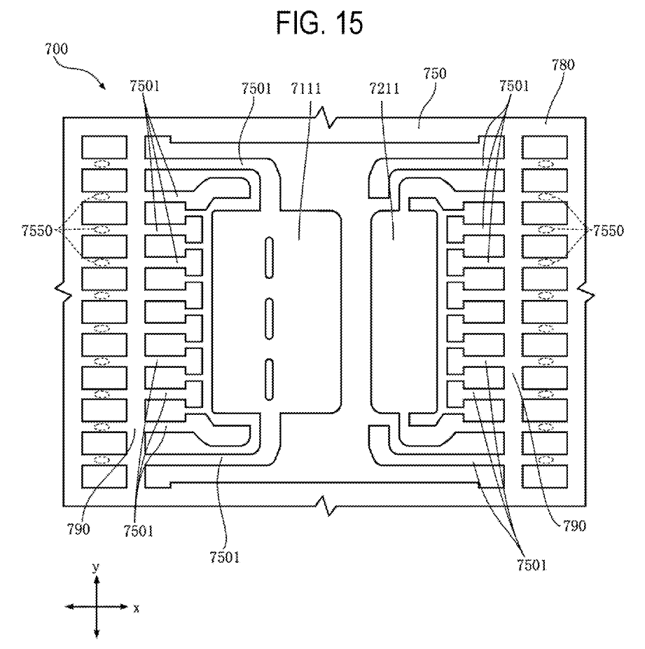

In the step of preparing the lead frame 700, the lead frame 700 is prepared as shown in FIG. 15. At this point, the lead frame 700 is formed only of a body 750. The body 750 may contain, for example, a metal such as Cu (copper), Ni (nickel), Fe (iron), or the like, or an alloy of the metal. The lead frame 700 may include, for example, portions that will become the island portion 7111 and the island portion 7211 described above, and a plurality of rod-shaped portions 7501, as well as an outer frame 780 and a dam bar 790 that connect these portions.

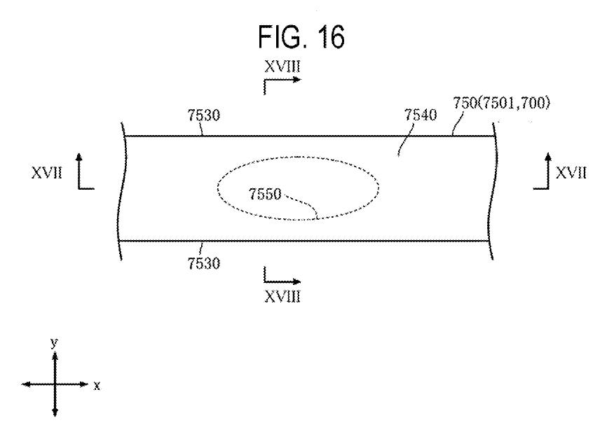

As shown in FIGS. 16 to 18, each rod-shaped portion 7501 extends along the first direction x. Each rod-shaped portion 7501 may include a bottom surface 7510, two side surfaces 7530, a top surface 7540, and a concave surface 7550.

The bottom surface 7510 faces the z1 side in the thickness direction z. The top surface 7540 faces the z2 side in the thickness direction z. The two side surfaces 7530 are located on either side of the first direction x and are located between the bottom surface 7510 and the top surface 7540 in the thickness direction z.

The concave surface 7550 is recessed toward the z2 side from the bottom surface 7510 in the thickness direction z. The concave surface 7550 occupies only a portion of the body 750 in the second direction y. In the illustrated example, the concave surface 7550 is spaced apart from the two side surfaces 7530 in the second direction y.

A specific shape of the concave surface 7550 is not particularly limited. The concave surface 7550 may be circular, elliptical, polygonal, or the like when viewed in the thickness direction z. In the illustrated example, the concave surface 7550 is elliptical when viewed in the thickness direction z. A three-dimensional shape of the concave surface 7550 may be, for example, a concavely curved surface, a bent surface, or the like. In the illustrated example, the concave surface 7550 is configured by a concavely curved surface. Such a concave surface 7550 may be formed, for example, by etching or punching a metal plate material.

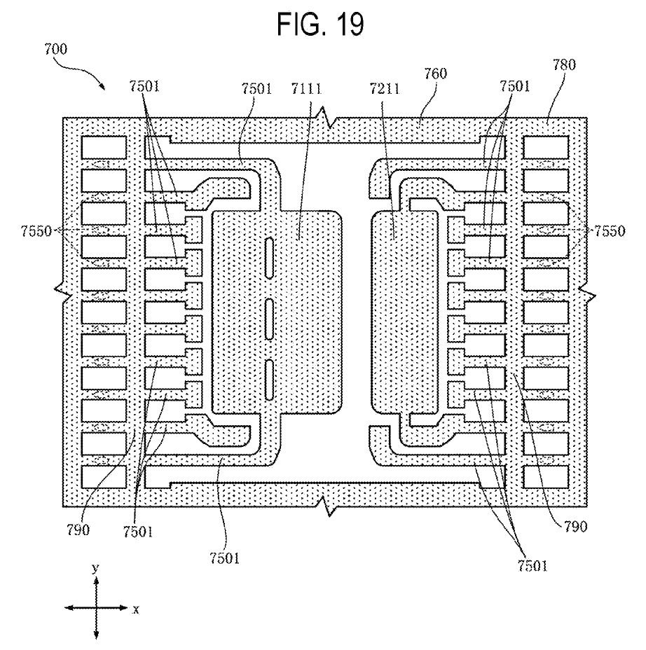

Next, as shown in FIG. 19, the metal layer 760 is formed. In the figure, for ease of understanding, a region where the metal layer 760 is formed is hatched. In this example, the metal layer 760 is formed so as to cover almost the entire body 750. The metal layer 760 may be formed of a single layer or a plurality of layers containing a metal such as Sn (tin), Ni (nickel), Pd (palladium), Au (gold), Ag (silver), or the like, or an alloy of the metal. The metal layer 760 is formed, for example, by a plating process.

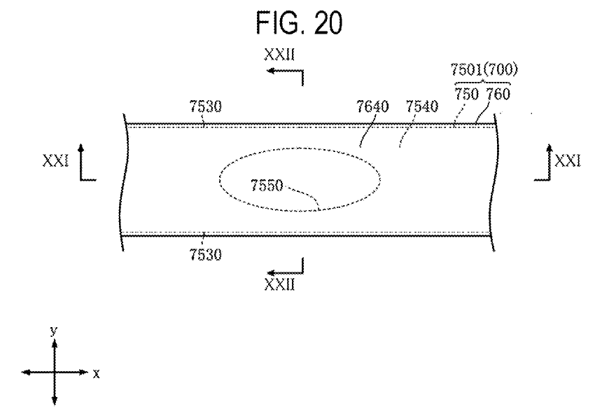

As shown in FIGS. 20 to 22, the metal layer 760 in the rod-shaped portion 7501 may include a bottom surface portion 7610, two side surface portions 7630, a top surface portion 7640, and a concave surface portion 7650. The bottom surface portion 7610 covers the bottom surface 7510. The two side surface portions 7630 cover the two side surfaces 7530. The top surface portion 7640 covers the top surface 7540. The concave surface portion 7650 covers the concave surface 7550. The concave surface portion 7650 may only cover at least a portion of the concave surface 7550. In the illustrated example, the concave surface portion 7650 is connected to the bottom surface 7510. Further, the concave surface portion 7650 covers the entire concave surface 7550.

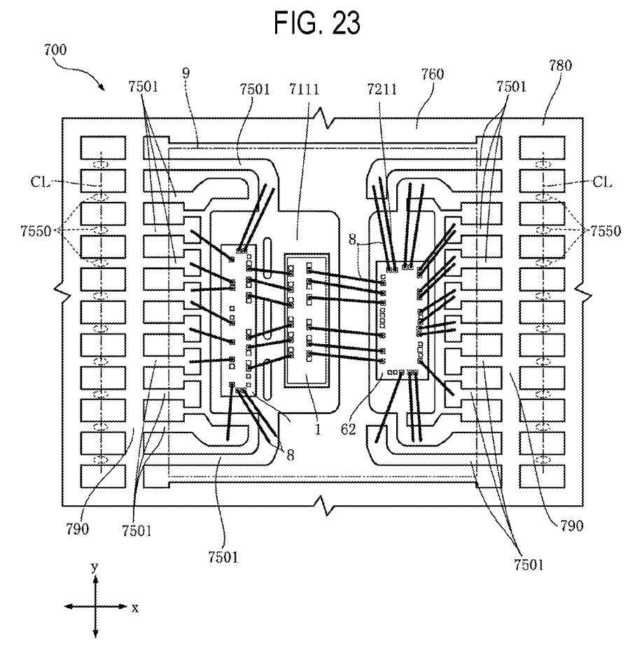

Next, as shown in FIG. 23, the step of mounting the semiconductor element 1 is performed. In addition to this step, the first semiconductor element 61 and the second semiconductor element 62 may be mounted. Further, after this step, a step of connecting the plurality of connecting members 8 may be performed. Then, the step of forming the sealing resin 9 is performed. In FIG. 23, the sealing resin 9 is indicated by an imaginary line. In addition to the region indicated by the imaginary line, a resin molded portion may be formed at any location.

Next, the lead frame 700 is cut. The lead frame 700 is cut along two cutting lines CL shown in FIG. 23. Further, for example, the dam bar 790 may be cut at appropriate locations along a plurality of cutting lines (not shown).

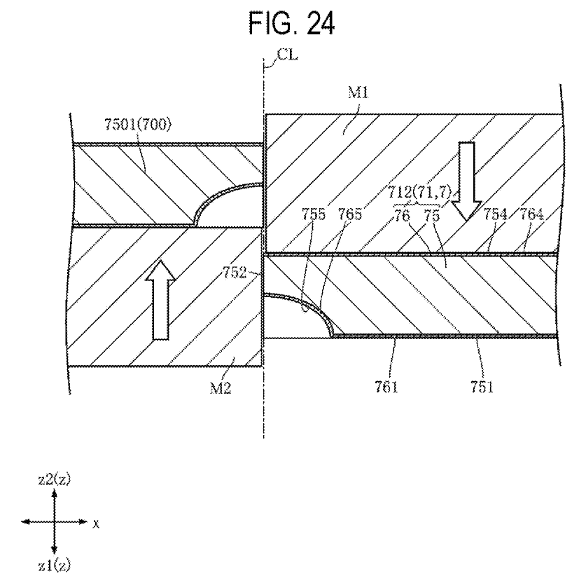

The cutting line CL intersects with the concave surface 7550. That is, in the process of cutting the lead frame 700, the concave surface 7550 is cut. A method of cutting the lead frame 700 is not particularly limited. In the example shown in FIG. 24, the cutting is performed using molds M1 and M2. The molds M1 and M2 are crossed in the thickness direction z while facing each other across the cutting line CL. Thus, the lead frame 700 is cut at the concave surface 7550. This cutting results in formation of the leads 7 each including the body 75 and the metal layer 76. A cut surface by the cutting is formed in the exposed portion 712 of the lead 7, and this cut surface becomes the end surface 752. Further, one side of the cut concave surface 7550 and one side of the cut concave surface portion 7650 become the concave surface 755 and the concave surface portion 765, respectively. Through the above steps, the semiconductor device A1 is obtained.

Next, an operation of the semiconductor device A1 is described.

According to this embodiment, as shown in FIGS. 12 and 13, the semiconductor device A1 may be mounted to a circuit board SU including an insulating plate SU1 and a wiring pattern SU2 by solder SL. In this mounting, the solder SL adheres to the concave surface portion 765. This increases mounting strength of the semiconductor device A1 to the circuit board SU by the solder SL.

The concave surface 755 occupies only a portion of the body 75 in the second direction y. Therefore, as shown in FIG. 13, the solder SL bites into the leads 7. This makes it possible to more effectively increase the mounting strength of the semiconductor device A1.

The concave surface 755 is spaced apart from the two side surfaces 753. This results in a structure in which, as shown in FIG. 13, the solder SL bites into a central portion of the exposed portion 712 in the second direction y. This is preferable for improving the mounting strength.

As shown in FIG. 12, the concave surface portion 765 is connected to the bottom surface portion 761, so that the solder SL is more easily attached to both the bottom surface portion 761 and the concave surface portion 765.

As shown in FIGS. 23 and 24, in the method of manufacturing the semiconductor device A1, the concave surface 7550 is cut when cutting the lead frame 700. This makes it possible to more reliably and easily form the concave surface 755 located at the tip of the exposed portion 712.

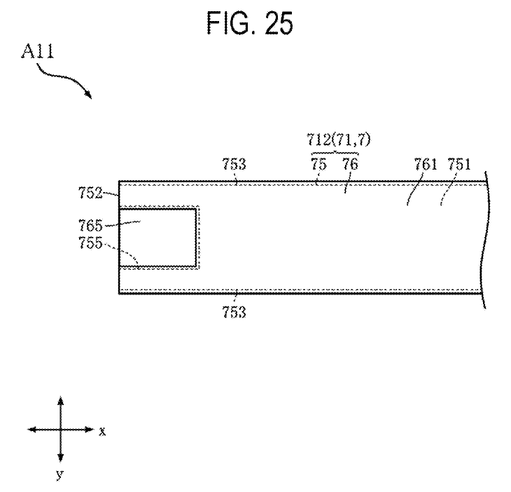

FIGS. 25 to 31 show modifications and other embodiments of the present disclosure. In these figures, elements that are the same as or similar to those of the above-described embodiment are designated by the same reference numerals. Furthermore, the configurations of the various parts in each modification and each embodiment may be combined with each other as appropriate within the scope that does not cause technical contradictions.

FIG. 25 shows a first modification of the semiconductor device A1. In a semiconductor device A11 of this modification, the concave surface 755 has a polygonal rectangular shape when viewed in the thickness direction z.

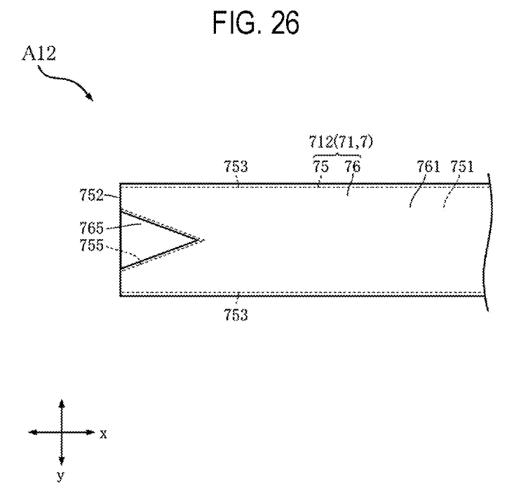

FIG. 26 shows a second modification of the semiconductor device A1. In a semiconductor device A12 of this modification, the concave surface 755 has a polygonal triangular shape when viewed in the thickness direction z.

It is possible to increase the mounting strength with the semiconductor device A11 and the semiconductor device A12. Further, as can be understood from these modifications, the specific shape of the concave surface 755 as viewed in the thickness direction z is not particularly limited.

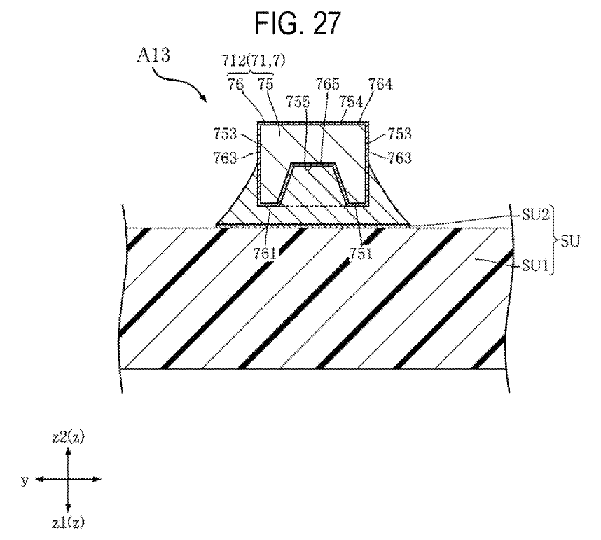

FIG. 27 shows a third modification of the semiconductor device A1. In a semiconductor device A13 of this modification, the concave surface 755 is formed by a bent surface. In the cross section shown, the concave surface 755 is formed by a bent surface including three mutually intersecting planes. In this modification as well, the size of the concave surface 755 in the second direction y increases toward the first side z1 in the thickness direction z.

It is possible to increase the mounting strength with the semiconductor device A13. As can be seen from these modifications, the cross-sectional shape of the concave surface 755 is not limited to a specific one.

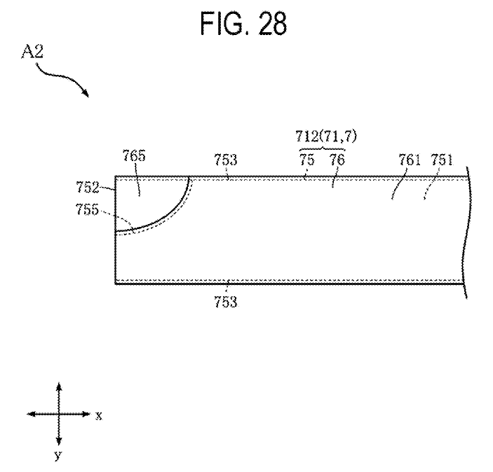

FIG. 28 shows a semiconductor device according to a second embodiment of the present disclosure. In a semiconductor device A2 of this embodiment, when viewed in the thickness direction z, the concave surface 755 is in contact with one of the two side surfaces 753 and is spaced apart from the other. That is, the concave surface 755 is recessed inward in the second direction y from one side surface 753.

It is possible to increase the mounting strength with the semiconductor device A2. As can be understood from this embodiment, the specific position of the concave surface 755 in the thickness direction z is not limited at all.

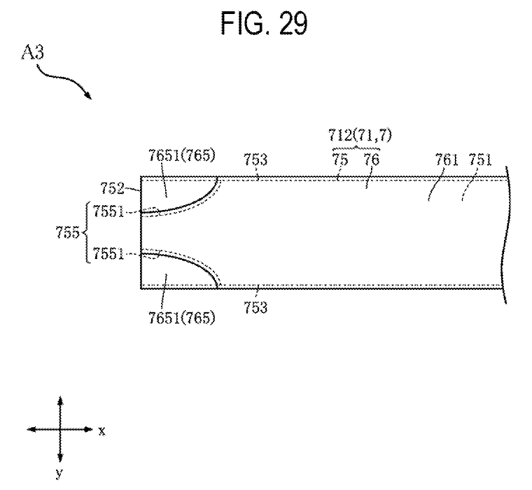

FIG. 29 shows a semiconductor device according to a third embodiment of the present disclosure. In a semiconductor device A3 of this embodiment, the concave surface 755 includes a plurality of separation regions 7551. The number of the plurality of separation regions 7551 is not particularly limited, and is two in the illustrated example.

The two separation regions 7551 are spaced apart from each other in the second direction y. A portion of the bottom surface 751 is interposed between the two separation regions 7551. The two separation regions 7551 are in contact with the two side surfaces 753, respectively, when viewed in the thickness direction z. Each of the two separation regions 7551 is recessed inward in the second direction y from each of the two side surfaces 753.

It is possible to increase the mounting strength with the semiconductor device A3. Further, the semiconductor device A3 includes a structure in which the solder SL bites into the leads 7 in the plurality of separation regions 7551. This is possible to further increase the mounting strength.

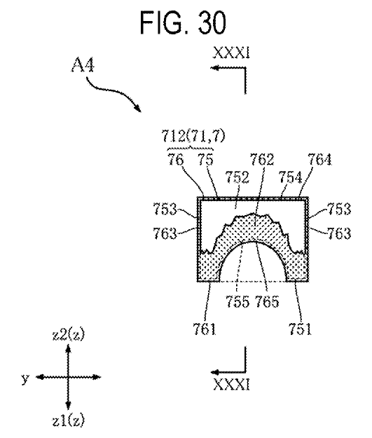

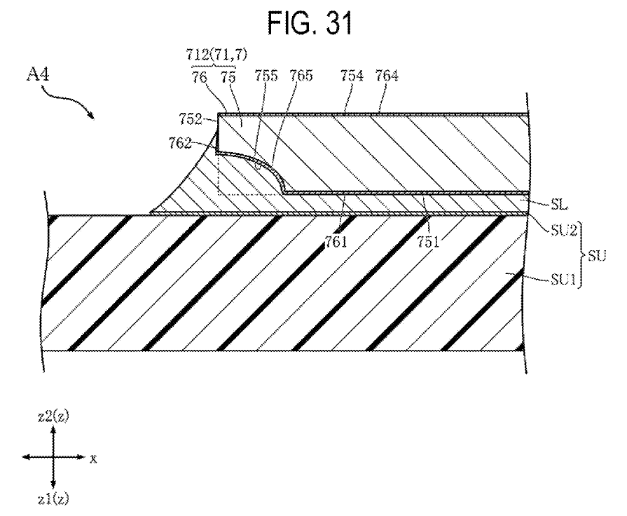

FIGS. 30 and 31 show a semiconductor device according to a fourth embodiment of the present disclosure. In a semiconductor device A4 of this embodiment, the metal layer 76 in the exposed portion 712 further includes an end surface portion 762. In FIG. 30, for ease of understanding, the end surface portion 762 is hatched.

The end surface portion 762 covers at least a portion of the end surface 752. In the illustrated example, the end surface portion 762 covers a portion of the end surface 752 on the first side z1 in the thickness direction z. A portion of the end surface 752 on the second side z2 in the thickness direction z is exposed from the end surface portion 762. The end surface portion 762 may cover the entire end surface 752. The end surface portion 762 is connected to the concave surface 755. The end surface portion 762 is connected to the bottom surface portion 761.

The end surface portion 762 may be formed, for example, as a result of a portion of the metal layer 760 being stretched by the mold M2 and adhering to the end surface 752 in the process of cutting the lead frame 700 shown in FIG. 24.

It is possible to increase the mounting strength with the semiconductor device A4. In addition, as shown in FIG. 31, in this embodiment, the solder SL may adhere to the end surface portion 762. This may further increase the mounting strength of the semiconductor device A4.

The semiconductor device and the method of manufacturing the semiconductor device according to the present disclosure are not limited to the above-described embodiments. The specific configurations of the semiconductor device and the method of manufacturing the semiconductor device according to the present disclosure may be freely modified in various ways.

### Supplementary Note 1

A semiconductor device (A1), including:

a semiconductor element (1);

a plurality of leads (7); and

a sealing resin (9),

wherein each of the plurality of leads (7) includes a body (75) and a metal layer (76) covering at least a portion of the body (75),

wherein at least one of the plurality of leads (7) includes a covered portion (711) covered with the sealing resin (9) and an exposed portion (712) exposed from the sealing resin (9),

wherein the body (75) in the exposed portion (712) includes a bottom surface (751) facing a first side (z1) in a thickness direction (z) of the semiconductor element (1), an end surface (752) with a tip facing a first direction (x) intersecting the thickness direction (z), and a concave surface (755) located between the bottom surface (751) and the end surface (752),

wherein the concave surface (755) occupies only a portion of the body (75) in a second direction (y) intersecting the thickness direction (z) and the first direction (x), and

wherein the metal layer (76) includes a bottom surface portion (761) covering the bottom surface (751) and a concave surface portion (765) covering the concave surface (755).

### Supplementary Note 2

The semiconductor device (A1) of Supplementary Note 1, wherein the body (75) in the exposed portion (712) includes two side surfaces (753) facing opposite to each other in the second direction.

### Supplementary Note 3

The semiconductor device (A1) of Supplementary Note 2, wherein the metal layer (76) includes two side surface portions (763) covering the two side surfaces (753).

### Supplementary Note 4

The semiconductor device (A1) of Supplementary Note 2 or 3, wherein the concave surface (755) is spaced apart from the two side surfaces (753).

### Supplementary Note 5

The semiconductor device (A2) of Supplementary Note 2 or 3, wherein the concave surface (755) is in contact with either of the two side surfaces (753).

### Supplementary Note 6

The semiconductor device (A3) of Supplementary Note 2 or 3, wherein the concave surface (755) includes two separation regions (7551) that are respectively in contact with the two side surfaces (753).

### Supplementary Note 7

The semiconductor device (A1) of any one of Supplementary Notes 1 to 6, wherein the concave surface (755) has a semicircular or semielliptical shape when viewed in the thickness direction (z).

### Supplementary Note 8

The semiconductor device (A11) of any one of Supplementary Notes 1 to 6, wherein the concave surface (755) has a polygonal shape when viewed in the thickness direction (z).

### Supplementary Note 9

The semiconductor device (A1) of any one of Supplementary Notes 1 to 8, wherein the concave surface (755) is formed by a concavely curved surface.

### Supplementary Note 10

The semiconductor device (A13) of any one of Supplementary Notes 1 to 8, wherein the concave surface (755) is formed by a bent surface.

### Supplementary Note 11

The semiconductor device (A1) of any one of Supplementary Notes 1 to 8, wherein a size of the concave surface (755) in the second direction (y) increases as the concave surface (755) extends toward the first side (z1) in the thickness direction (z).

### Supplementary Note 12

The semiconductor device (A4) of any one of Supplementary Notes 1 to 11, wherein the metal layer (76) includes an end surface portion (762) covering at least a portion of the end surface (752).

### Supplementary Note 13

The semiconductor device (A4) of Supplementary Note 12, wherein the end surface portion (762) is connected to the concave surface portion (765).

### Supplementary Note 13-1

The semiconductor device (A4) of Supplementary Note 12 or 13, wherein the end surface portion (762) is connected to the bottom surface portion (761).

### Supplementary Note 14

The semiconductor device (A1) of any one of Supplementary Notes 1 to 13, wherein the semiconductor element (1) is an insulating signal transmission element, and

wherein the semiconductor device (A1) further includes:

a first semiconductor element (61) and a second semiconductor element (62) configured to transmit and receive signals to and from each other in an insulated state via the semiconductor element (1).

### Supplementary Note 15

A method of manufacturing a semiconductor device (A1), including:

preparing a lead frame (700) including a body (750) which includes a rod-shaped portion (7501) extending in a first direction (x);

mounting a semiconductor element (1) on the lead frame (700);

forming a sealing resin (9) configured to cover a portion of the lead frame (700) and the semiconductor element (1); and

cutting the lead frame (700),

wherein the rod-shaped portion (7501) includes a bottom surface (7510) facing a first side (z1) in a thickness direction (z) intersecting the first direction (x) and a concave surface (7550) recessed from the bottom surface (7510),

wherein the method further includes:

forming a metal layer (760) including a bottom surface portion (7610) covering the bottom surface (7510) and a concave surface portion (7650) covering the concave surface (7550) after the preparing the lead frame (700) and before the mounting the semiconductor element (1), and

wherein the concave surface (7550) is cut in the cutting the lead frame (700).

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor element;
a plurality of leads; and
a sealing resin,
wherein each of the plurality of leads includes a body and a metal layer covering at least a portion of the body,
wherein at least one of the plurality of leads includes a covered portion covered with the sealing resin and an exposed portion exposed from the sealing resin,
wherein the body in the exposed portion includes a bottom surface facing a first side in a thickness direction of the semiconductor element, an end surface with a tip facing a first direction intersecting the thickness direction, and a concave surface located between the bottom surface and the end surface,
wherein the concave surface occupies only a portion of the body in a second direction intersecting the thickness direction and the first direction, and
wherein the metal layer includes a bottom surface portion covering the bottom surface and a concave surface portion covering the concave surface.

2. The semiconductor device of claim 1, wherein the body in the exposed portion includes two side surfaces facing opposite to each other in the second direction.

3. The semiconductor device of claim 2, wherein the metal layer includes two side surface portions covering the two side surfaces.

4. The semiconductor device of claim 2, wherein the concave surface is spaced apart from the two side surfaces.

5. The semiconductor device of claim 2, wherein the concave surface is in contact with either of the two side surfaces.

6. The semiconductor device of claim 2, wherein the concave surface includes two separation regions that are respectively in contact with the two side surfaces.

7. The semiconductor device of claim 1, wherein the concave surface has a semicircular or semielliptical shape when viewed in the thickness direction.

8. The semiconductor device of claim 1, wherein the concave surface has a polygonal shape when viewed in the thickness direction.

9. The semiconductor device of claim 1, wherein the concave surface is formed by a concavely curved surface.

10. The semiconductor device of claim 1, wherein the concave surface is formed by a bent surface.

11. The semiconductor device of claim 1, wherein a size of the concave surface in the second direction increases as the concave surface extends toward the first side in the thickness direction.

12. The semiconductor device of claim 1, wherein the metal layer includes an end surface portion covering at least a portion of the end surface.

13. The semiconductor device of claim 12, wherein the end surface portion is connected to the concave surface portion.

14. The semiconductor device of claim 1, wherein the semiconductor element is an insulating signal transmission element, and
wherein the semiconductor device further comprises:
a first semiconductor element and a second semiconductor element configured to transmit and receive signals to and from each other in an insulated state via the semiconductor element.

15. A method of manufacturing a semiconductor device, comprising:
preparing a lead frame including a body which includes a rod-shaped portion extending in a first direction;
mounting a semiconductor element on the lead frame;
forming a sealing resin configured to cover a portion of the lead frame and the semiconductor element; and
cutting the lead frame,
wherein the rod-shaped portion includes a bottom surface facing a first side in a thickness direction intersecting the first direction and a concave surface recessed from the bottom surface,
wherein the method further comprises:
forming a metal layer including a bottom surface portion covering the bottom surface and a concave surface portion covering the concave surface after the preparing the lead frame and before the mounting the semiconductor element, and
wherein the concave surface is cut in the cutting the lead frame.
